(19) United States
(12) Patent Application Publication
(10) Pub. No.: US 2008/0272779 A1
(43) Pub. Date: Nov. 6, 2008

(54) Determination of Distribution Information of a Contrast Agent by Mr Molecular Imaging

(75) Inventors: Hannes Dahnke, Hamburg (DE); Tobias Schaeffter, Blackheath (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/915,626

(22) PCT Filed: May 24, 2006
(86) PCT No.: PCT/IB06/51657

§ 371 Date: Nov. 27, 2007

(30) Foreign Application Priority Data
Jun. 1, 2005 (EP) 05104726.4

(51) Int. Cl. G01R 33/50

(52) U.S. Cl. 324/309

(57) ABSTRACT

MR based molecular imaging is used for the quantification of contrast agent concentrations. According to an exemplary embodiment of the present invention, a difference between R2 and R2* relaxation rates of a contrast agent is determined on the basis of data measured after contrast agent application. This may provide for an in vivo information relating to a compartmentalization or binding status of the contrast agent, and thus may improve the significance of the examination result.

The present invention relates to the field of molecular imaging. In particular, the present invention relates to an examination apparatus for examination of an object of interest, to an image processing device, to a method of examining an object of interest, to a computer-readable medium and to a program element.

Magnetic Resonance (MR) based molecular imaging is strongly supported by an accurate quantification of contrast agents. The monitoring of therapy effects like changing tumour vascularization and perfusion are of great importance in the clinical routine. Detecting a therapy effect requires an accurate and quantitative determination of contrast agent distributions. It is of particular interest whether the contrast agent is incorporated into cells or dissolved in liquid, e.g. in blood.

It may be desirable to have an improved distribution determination of contrast agents.

According to an exemplary embodiment of the present invention, an examination apparatus for examination an object of interest may be provided, the examination apparatus comprising a determination unit adapted for determining a distribution information of a contrast agent on the basis of a difference between a first relaxation time of the contrast agent and a second relaxation time of the contrast agent.

Therefore, by determining the difference between the first relaxation time and the second relaxation time, information about the distribution of the contrast agent may be determined by comparing the two relaxation times during a measurement. This may improve the significance of the examination result of MR imaging relaxometry.

According to another exemplary embodiment of the present invention, the first relaxation time is a spin-spin transverse relaxation time, wherein the second relaxation time is based on the first relaxation time and incorporates magnetic field inhomogeneities.

In other words, the first relaxation time may, according to this exemplary embodiment of the present invention, the T2 relaxation time and the second relaxation time is the T2* relaxation time.

It should be noted, that R2 (also referred to as spin-spin transverse relaxation rate) is defined as the inverse of the T2 relaxation time (1/T2). R2* is defined as the inverse of the T2* relaxation time, which includes T2 and additionally incorporates magnetic field inhomogeneities.

According to another exemplary embodiment of the present invention, the examination apparatus further comprises an acquisition unit adapted for acquiring a dataset of the object of interest, wherein the determination of the difference is performed on the basis of the acquired dataset.

For example, T2 may be measured by means of a multi spin-echo sequence and T2* by means of a multi gradient-echo sequence. But it should be noted that other methods may be used to measure T2 and T2* within the same sequence. Therefore, information (relating e.g. to T2 and T2*) may be acquired at the same time. Thus changes between the two measurements which otherwise may falsify the result may be excluded.

Therefore, the object of interest may be examined by acquiring a respective measurement dataset of the object of interest and by determining the difference between the two relaxation times by analyzing the measured dataset. This may provide for an in vivo examination procedure.

According to another exemplary embodiment of the present invention, the distribution information comprises information about a binding status of the contrast agent on the basis of the difference.

Therefore, the question whether the contrast agent is bound to the target can be addressed by this measurement.

According to another exemplary embodiment of the present invention, the distribution information comprises information about a heterogeneity of the distribution.

For example, if the distribution is homogeneous, then the R2 values may equal respective R2* values. Increasing heterogeneity of the distribution may result in an increasing difference between respective R2 and R2* values (R2*>R2).

According to another exemplary embodiment of the present invention, the distribution information comprises information about a status of internalization of the contrast agent into cells of the object of interest.

This may provide for further information relating to internal properties of the object of interest.

According to another exemplary embodiment of the present invention, the contrast agent is a targeted contrast agent.

According to still another exemplary embodiment of the present invention, the contrast agent is a super paramagnetic iron-oxide contrast agent (SPIO).

According to another exemplary embodiment of the present invention, the examination apparatus may be applied as a baggage inspection apparatus, a medical application apparatus, a material testing apparatus or a material science analysis apparatus. A field of application of the invention may be material science analysis, since the defined functionality of the invention may be allow for a secure, reliable and highly accurate analysis of a material.

According to another exemplary embodiment of the present invention, an image processing device for examination of an object of interest may be provided, the image processing device comprising a memory for storing a dataset of the object of interest. Furthermore, the image processing device may comprise a determination unit adapted for determining a distribution information of a contrast agent on the basis of a difference between a first relaxation time of the contrast agent and a second relaxation time of the contrast agent.

Therefore, an image processing device may be provided which is adapted for performing an improved distribution determination of contrast agents, which may result in a more specific or more significant examination result.

According to another exemplary embodiment of the present invention, a method of examination of an object of interest is provided, the method comprising the step of determining a distribution information of a contrast agent on the basis of a difference between a first relaxation time of the contrast agent and a second relaxation time of the contrast agent. Furthermore, the method may comprise the step of acquiring a dataset of the object of interest, wherein the determination of the difference is performed on the basis of the acquired dataset. The first relaxation time may be a spin-spin transverse relaxation time and the second relaxation time may be based on the first relaxation time and may further incorporate magnetic field inhomogeneities.

Thus, a method is provided for an examination of an object of interest by MR molecular imaging which may lead to an improved distribution determination of contrast agents resulting in vivo information relating to a compartmentalization or to a binding status of the contrast agent. This may provide for a more detailed analysis of the object of interest.

According to another exemplary embodiment of the present invention, a computer-readable medium may be provided, in which a computer program of examination of an object of interest is stored, which, when being executed by a processor, is adapted to carry out the above-mentioned method steps.

Furthermore, the present invention relates to a program element of examination of an object of interest, which may be stored on the computer-readable medium. The program element may be adapted to carry out the steps of acquiring a dataset of the object of interest and determining a distribution information of a contrast agent on the basis of a difference between a first relaxation time of the contrast agent and a second relaxation time of the contrast agent, wherein the determination of the difference is performed on the basis of the acquired dataset.

The program element may preferably be loaded into working memories of a data processor. The data processor may thus be equipped to carry out exemplary embodiments of the methods of the present invention. The computer program may be written in any suitable programming language, such as, for example, C++ and may be stored on a computer-readable medium, such as a CD-ROM. Also, the computer program may be available from a network, such as the WorldWideWeb, from which it may be downloaded into image processing units or processors, or any suitable computers.

It may be seen as the gist of an exemplary embodiment of the present invention that a difference between R2 and R2* relaxation rates of tissue is determined on the basis of data measured after contrast agent application. This may provide an in vivo information relating to a compartmentalization or binding status of the contrast agent. Thus, the significance of the examination result of MR imaging relaxometry may be improved.

These and other aspects of the present invention will become apparent from and elucidated with reference to the embodiment described hereinafter.

Exemplary embodiments of the present invention will be described in the following, with reference to the following drawings.

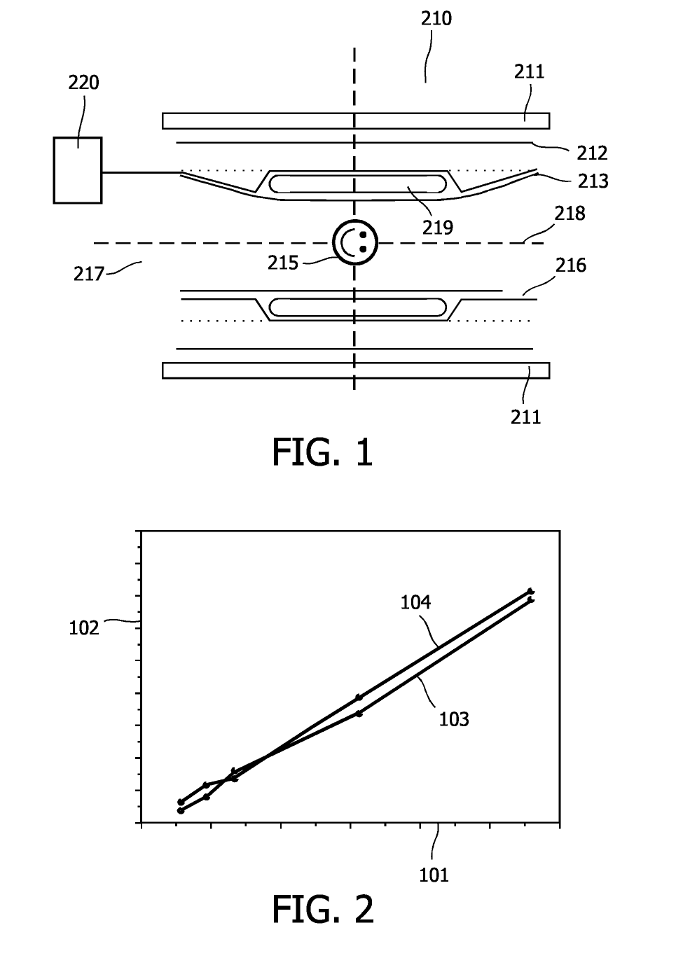

FIG. 1 shows a simplified schematic representation of an MR scanner according to an exemplary embodiment of the present invention.

FIG. 2 schematically shows R2 and R2* values of SPIO dissolved in water.

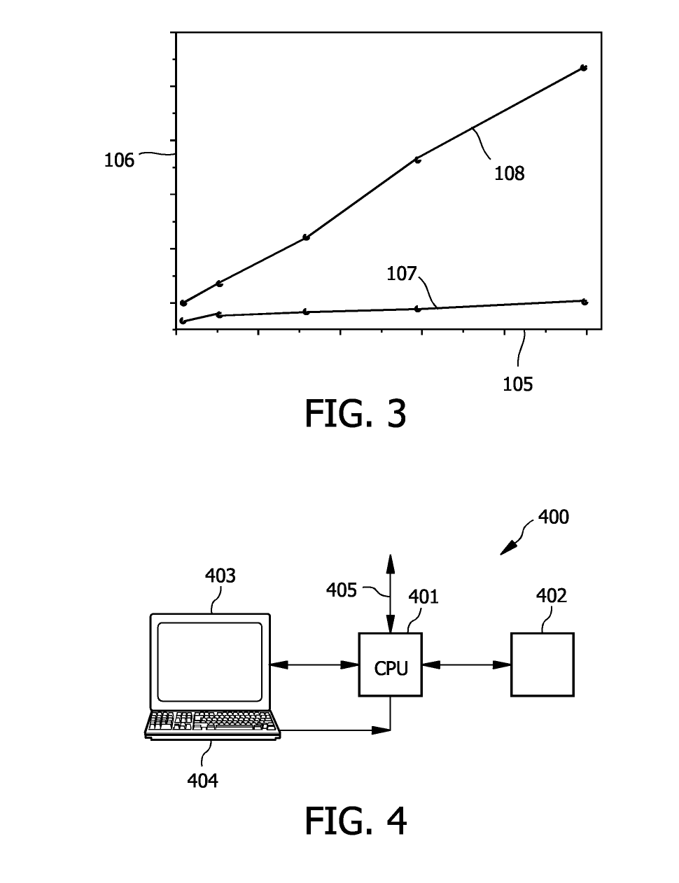

FIG. 3 schematically shows R2 and R2* values of SPIO incorporated into cells.

FIG. 4 shows an exemplary embodiment of an image processing device according to the present invention, for executing an exemplary embodiment of a method in accordance with the present invention.

The illustration in the drawings is schematically. In different drawings, similar or identical elements may be provided with the same reference numerals.

FIG. 1 shows a simplified schematic representation of an embodiment of an MR scanner system according to the present invention. The MR scanner system comprises coils 210 which are arranged along an axis 218 and surround an examination space 217, in which a patient 215 which has to be examined is positioned. However, it should be noted, that the described examination apparatus may as well be used in the field of baggage inspection or material science analysis. Thus, the object of interest 215 may be an item of baggage or a material which has to be analyzed.

Advantageously, the object of interest 215 lies on a movable table or conveyor belt 216, which is disposed at the lower part of the examination space 217. The system of coils 210 surrounding the examination space 217 comprises an HF-coil 219, an actively shielded arrangement of gradient coils comprising an inner coil 213 and an actively shielded coil or shield 212 and a cryostat 211, in which the coils are arranged in order to be cooled down during generation of the magnetic field. The arrangement of gradient coils 213, 212 may be connected to a gradient amplifier 220 and to a determination unit (not depicted in FIG. 1) adapted for determining a distribution information of a contrast agent on the basis of a difference between a first relaxation time of the contrast agent and a second relaxation time of the contrast agent, wherein the first relaxation time is a spin-spin transverse relaxation time and wherein the second relaxation time is based on the first relaxation time and incorporates magnetic field inhomogeneities.

Furthermore, the MR scanner system may comprise a motor control unit with respective motors (not depicted in FIG. 1), for example for moving the conveyor belt 216.

MR imaging based molecular imaging is used for a quantification of contrast agent concentrations. The R2 (=1/T2) and R2* (=1/T2*) relaxation rates contain information about the concentration of super paramagnetic iron-oxide contrast agents (SPIOs). In addition to that, the question, whether the contrast agent is incorporated into cells or dissolved in liquid, e.g. in blood is of particular interest. The difference between T2 and T2*(or between R2 and R2*) may contain information about the distribution of these contrast agents. If the SPIOs are compartmentalized in cells the R2* relaxation rate is higher than R2. In case the SPIOs are dissolved in liquid, the relaxation rates are similar (as may be seen from FIG. 2).

According to an aspect of the present invention, the compartmentalization of SPIOs may be measured in vivo by means of these differences in R2 and R2*. This may widen the application of MR imaging relaxometry by measuring an additional parameter that contains information about the binding status of contrast agents, which is especially interesting in the context of targeted contrast agents. The question whether the contrast agent is bound to the target may be addressed by this measurement. Therefore, information of R2*-R2 may help to determine the binding status or the status of internalization into cells of the SPIO contrast agents and therefore may improve the significance of the examination result.

FIG. 2 shows a schematic representation of R2 and R2* values of SPIO dissolved in water. R2 is defined as the inverse of the T2 relaxation time (1/T2), also referred to as spin-spin transverse relaxation time. R2* is defined as the inverse of the T2* relaxation time, which includes T2 and additionally incorporates magnetic field inhomogeneities.

Horizontal axis 101 shows an iron concentration in arbitrary units, e.g. in μg/ml, ranging from. e.g. approximately 0 μg/ml iron concentration to approximately 28 μg/ml iron concentration. The vertical axis 102 shows the relaxation rate in arbitrary units, e.g. 1/ms, ranging from approximately 0 ms-0.15 ms.

As may be seen from FIG. 2, there is hardly no difference detectable between the R2 values 103 and the R2* values 104. Therefore, the relaxation rates do not differ if the contrast agent is dissolved in water and is therefore not compartmentalized in cells (at least within the available measurement accuracy).

FIG. 3 shows R2 and R2* values of SPIO (Super Paramagnetic Iron-Oxide contrast agents) incorporated into cells. The horizontal axis 105 corresponds to horizontal axis 101 in FIG. 2 and the vertical axis 106 corresponds to vertical axis 102 in FIG. 2.

As may be seen from FIG. 3, there is a clear difference between the R2 relaxation rate 107 and the R2* relaxation rate 108. Therefore, by determining the difference between the two relaxation rates (or by determining the difference between the two respective relaxation times), information about the binding status or the status of internalization or compartmentalization into the cells may be determined.

FIG. 4 depicts an exemplary embodiment of an image processing device according to the present invention for executing an exemplary embodiment of the method in accordance with the present invention. The image processing device 400 depicted in FIG. 5 comprises a central processing unit (CPU) or image processor 401 connected to a memory 402 for storing an image depicting an object of interest, such as a patient or a material to be analyzed. The data processor 401 may be connected to a plurality of input/output network or diagnosis devices, such as an MR device. The data processor 401 may furthermore be connected to a display device 403, for example, a computer monitor, for displaying information or an image computed or adapted in the data processor 401. An operator or user may interact with the data processor 401 via a keyboard 404 and/or other output devices, which are not depicted in FIG. 5. Furthermore, via the bus system 405, it may also be possible to connect the image processing and control processor 401 to, for example, a motion monitor, which monitors a motion of the object of interest. In case, for example, a lung of a patient is imaged, the motion sensor may be an exhalation sensor. In case, the heart is imaged, the motion sensor may be an electrocardiogram.

Exemplary embodiments of the invention may be sold as a software option to MR scanner console workstations.

It should be noted that the term “comprising” does not exclude other elements or steps and the “a” or “an” does not exclude a plurality and that a single processor or system may fulfill the functions of several means or units recited in the claims. Also elements description in association with different embodiments may be combined.

It should also be noted, that any reference signs in the claims shall not be construed as limiting the scope of the claims.

1. Magnetic resonance examination apparatus for examination of an object of interest (215), the magnetic resonance examination apparatus comprising:
a determination unit (401) adapted for determining a distribution information of a contrast agent on the basis of a difference between a first relaxation time of the contrast agent and a second relaxation time of the contrast agent.

2. The examination apparatus of claim 1,
wherein the first relaxation time is a spin-spin transverse relaxation time; and
wherein the second relaxation time is based on the first relaxation time and incorporates magnetic field inhomogeneities.

3. The examination apparatus of claim 1, further comprising:
an acquisition unit (212, 213) adapted for acquiring a dataset of the object of interest (215);
wherein the determination of the difference is performed on the basis of the acquired dataset.

4. The examination apparatus of claim 1,
wherein the distribution information comprises information about a heterogeneity of the distribution.

5. The examination apparatus of claim 1,
wherein the distribution information comprises information about a binding status of the contrast agent on the basis of the difference.

6. The examination apparatus of claim 1,
wherein the distribution information comprises information about a status of internalization of the contrast agent into cells of the object of interest (215).

7. The examination apparatus of claim 1,
wherein the contrast agent is a targeted contrast agent.

8. The examination apparatus of claim 1,
wherein the contrast agent is a super paramagnetic iron-oxide contrast agent.

9. The examination apparatus of claim 1, configured as one of the group consisting of a baggage inspection apparatus, a medical application apparatus, a material testing apparatus and a material science analysis apparatus.

10. An image processing device for examination of an object of interest (215), the image processing device comprising:
a memory for storing a dataset of the object of interest (215);
a determination unit (401), being adapted for determining a distribution information of a contrast agent on the basis of a difference between a first relaxation time of the contrast agent and a second relaxation time of the contrast agent.

11. A computer-readable medium (402), in which a computer program of examination of an object of interest (215) is stored which, when being executed by a processor (401), is adapted to carry out the step of:
determining a distribution information of a contrast agent on the basis of a difference between a first relaxation time of the contrast agent and a second relaxation time of the contrast agent.

12. A program element of examination of an object of interest (215), which, when being executed by a processor (401), is adapted to carry out the step of:
determining a distribution information of a contrast agent on the basis of a difference between a first relaxation time of the contrast agent and a second relaxation time of the contrast agent.

13. A method of examination of an object of interest (215), the method comprising the step of:
determining a distribution information of a contrast agent on the basis of a difference between a first relaxation time of the contrast agent and a second relaxation time of the contrast agent.

14. The method of claim 13, further comprising the step of:
acquiring a dataset of the object of interest (215);
wherein the determination of the difference is performed on the basis of the acquired dataset;
wherein the first relaxation time is a spin-spin transverse relaxation time; and
wherein the second relaxation time is based on the first relaxation time and incorporates magnetic field inhomogeneities.
